(19) United States
(12) Patent Application Publication
(10) Pub. No.: US 2013/0093103 A1
(43) Pub. Date: Apr. 18, 2013

(54) Layered Semiconductor Package

(71) Applicants: Hyun Joo Kim, Chungcheongnam-do (KR); Yong Ha Jung, Incheon (KR)

(72) Inventors: Hyun Joo Kim, Chungcheongnam-do (KR); Yong Ha Jung, Incheon (KR)

(73) Assignee: HANA MICRON INC, CHUNGSHEONGNAM-DO (KR)

(21) Appl. No.: 13/805,950

(22) PCT Filed: Jun. 1, 2011
(86) PCT No.: PCT/KR11/03990

§ 371 Date: Dec. 20, 2012

(30) Foreign Application Priority Data
Jun. 22, 2010 (KR) 10-2010-0058879

(51) Int. Cl. H01L 25/065

(52) U.S. Cl. CPC H01L 25/0657
USPC 257/777

(57) ABSTRACT

Provided is a layered semiconductor package. The present invention comprises: a substrate having a first connection pad and a second connection pad on the upper surface thereof; a first cascade chip-layered body mounted on the substrate in which a plurality of first semiconductor chips are layered in a stepped form so as to expose a first bonding pad to the outside; at least one spacer layered on the upper surface of the uppermost semiconductor chip of the first chip-layered body so as to expose a bonding pad of the uppermost semiconductor chip; a second cascade chip-layered body mounted on the upper surface of the spacer in which a plurality of second semiconductor chips are layered in a stepped form so as to expose a second bonding pad to the outside; a first conductive wire for electrically connecting the first bonding pad of the first semiconductor chip and the first connection pad of the substrate; and a second conductive wire for electrically connecting the second bonding pad of the second semiconductor chip and the second connection pad of the substrate.

### TECHNICAL FIELD

The present invention relates to a stacked semiconductor package, and, more particularly, to a stacked semiconductor package which may ensure a space so as to maximally prevent contact between semiconductor chips protruding to one side and a conductive wire upon wire bonding, and may ensure a supporting force so as to minimize cracking and movement of semiconductor chips due to an external force.

### BACKGROUND ART

With the recent advancement of the semiconductor industry and the various demands of users, electronic devices are manufactured to be much smaller and lighter, and to have larger capacities and perform multiple functions, and techniques for packaging semiconductor chips used in such electronic devices are intended to form the same or different semiconductor chips into a single unit package depending on the needs.

Chipscale packages wherein the size of a semiconductor package is about 110˜120% of the size of a semiconductor chip or die and stacked semiconductor packages comprising a plurality of semiconductor chips stacked to increase the data capacity and the processing speed of the semiconductor devices have been developed.

In the case of a stacked semiconductor package comprising a plurality of semiconductor chips which are stacked, high technology for connecting bonding pads of stacked semiconductor chips and connection pads of a substrate using conductive wires is required.

Thus, to increase data capacity and processing speed by stacking more semiconductor chips in a limited space, the thickness of semiconductor chips has been reduced, and thereby semiconductor chips these days have a thickness of 50˜100 μm.

FIG. 4 illustrates a conventional stacked semiconductor package. The conventional stacked semiconductor package 1 includes a first cascade chip-layered body 20 configured such that a plurality of semiconductor chips 21 is obliquely stacked in a stepped shape on a substrate 10 and bonding pads 22 are thus externally exposed to one side of the top of each of the chips, and a second cascade chip-layered body 30 configured such that a plurality of semiconductor chips 31 is obliquely stacked in a stepped shape in the opposite direction on the first cascade chip-layered body 20 and thus bonding pads 32 are externally exposed to the other side of the top of each of the chips.

The bonding pads 22, 32 of the semiconductor chips 21, 31 of the first and second cascade chip-layered bodies 20, 30 are wire-bonded to connection pads 12, 13 provided on the upper surface of the substrate 10 by means of a plurality of conductive wires 23, 33.

In FIG. 4, the reference numeral 14 designates solder balls provided on the lower surface of the substrate, and the reference numeral 50 designates a molding unit made of a resin on the substrate.

However, in the fabrication of such a conventional stacked semiconductor package 1, in the course of bonding the semiconductor chips 21 of the first cascade chip-layered body 20 obliquely stacked in a stepped shape on the substrate 10 to the connection pad 12 of the substrate by means of the conductive wires 23, a loop formed at the top of the conductive wire 23 comes into contact with the semiconductor chip 31 of the second cascade chip-layered body 30 having an upper overhang shape protruding in the right side in the drawing corresponding to the wire bonding region in the stack structure, undesirably causing an electrical short, and furthermore, in the course of forming the molding unit, contact occurs between the semiconductor chip and the conductive wire which is swept due to the injected resin.

Also, in the course of bonding the bonding pads 32 of the semiconductor chips 31 obliquely stacked in a stepped shape on the first cascade chip-layered body 29 to the connection pad 13 of the substrate by means of the conductive wires 33, when an external force is applied directly downward to the bonding pads 32 exposed to one side of the top of each of the chips, there is no structure for supporting, from below, the first cascade chip-layered body 20 having a lower overhang shape protruding to the left side in the drawing, and thus bouncing is caused upon bonding, undesirably making it difficult to perform a precise wire bonding process, incurring poor bonding, and causing cracking of the stacked semiconductor chips.

Upon wire bonding, contact between the conductive wire 23 of the first cascade chip-layered body 20 and the semiconductor chip 31 of the second cascade chip-layered body 30 and damage to the semiconductor chips 21 of the first cascade chip-layered body 20 due to an external force may become increasingly frequent in proportion to a decrease in the thickness of the semiconductor chips.

### DISCLOSURE

### Technical Problem

Accordingly, the present invention has been made keeping in mind the above problems occurring in the related art, and an object of the present invention is to provide a stacked semiconductor package which may ensure a space so as to maximally prevent contact between semiconductor chips protruding to one side and a conductive wire upon wire bonding, and may also ensure a supporting force so as to minimize cracking and movement of semiconductor chips due to an external force.

### Technical Solution

In order to accomplish the above object, the present invention provides a stacked semiconductor package, comprising a substrate having a first connection pad and a second connection pad formed on an upper surface thereof; a first cascade chip-layered body comprising a plurality of first semiconductor chips stacked in a stepped shape on the substrate so as to externally expose first bonding pads; at least one spacer formed on an upper surface of an uppermost semiconductor chip of the first cascade chip-layered body so as to externally expose a bonding pad of the uppermost semiconductor chip; a second cascade chip-layered body comprising a plurality of second semiconductor chips stacked in a stepped shape on an upper surface of the spacer so as to externally expose second bonding pads; a first conductive wire which electrically connects the first bonding pads of the first semiconductor chips and the first connection pad of the substrate; and a second conductive wire which electrically connects the second bonding pads of the second semiconductor chips and the second connection pad of the substrate.

Preferably, the spacer is disposed in a stepped shape between the uppermost semiconductor chip of the first cascade chip-layered body and a lowermost semiconductor chip of the second cascade chip-layered body.

Preferably, the spacer is disposed to overlap with the uppermost semiconductor chip of the first cascade chip-layered body so that a lower surface of one end thereof is exposed downward.

Preferably, a support member having a predetermined height is provided on the upper surface of the substrate so that an upper end of the support member is in contact with one end of the spacer or with one end of the semiconductor chip of the second cascade chip-layered body to support the second cascade chip-layered body.

Preferably, the substrate includes a molding unit which protects the first cascade chip-layered body and the second cascade chip-layered body from an external environment.

### Advantageous Effects

According to the present invention, a spacer having a predetermined thickness is provided between a first cascade chip-layered body and a second cascade chip-layered body, whereby a space having a large vertical gap can be ensured between an upper overhang region of the second cascade chip-layered body and a first bonding pad of an uppermost semiconductor chip of the first cascade chip-layered body, thus preventing contact between the semiconductor chips of the second cascade chip-layered body protruding to one side and the loop at the top of a first conductive wire upon wire bonding using the first conductive wire, ultimately warding off an electrical short.

Also, a support member having a predetermined height the upper end of which is in contact with the second cascade chip-layered body or the spacer is provided so as to support the second cascade chip-layered body obliquely stacked on the spacer, and thus upon wire bonding using a second conductive wire, cracking and movement of the semiconductor chips stacked on the first cascade chip-layered body due to an external force transferred directly downward to one end of the second cascade chip-layered body can be minimized or prevented, consequently increasing the reliability and quality of products.

### DESCRIPTION OF DRAWINGS

FIG. 1 is a cross-sectional view illustrating a stacked semiconductor package according to a first embodiment of the present invention;

FIG. 2 is a cross-sectional view illustrating a stacked semiconductor package according to a second embodiment of the present invention;

FIG. 3 is a cross-sectional view illustrating a stacked semiconductor package according to a third embodiment of the present invention; and

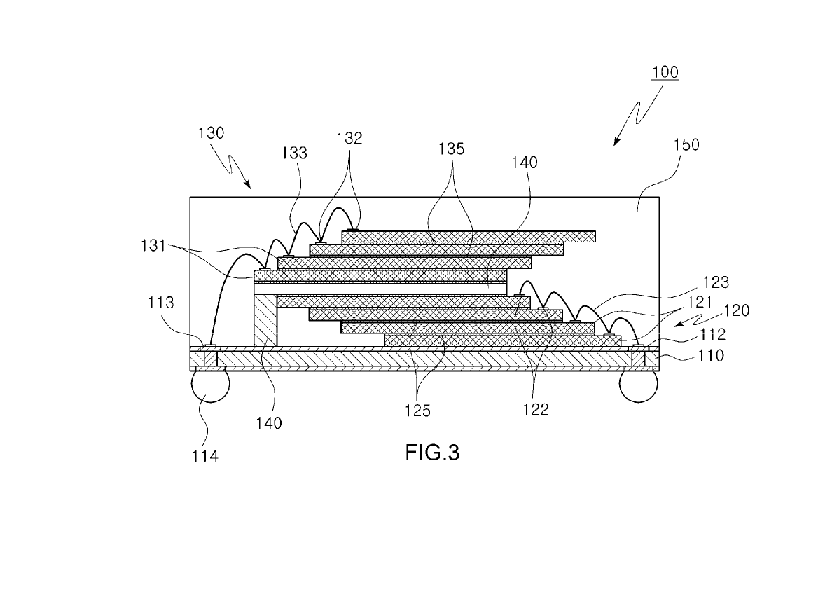

FIG. 4 is a cross-sectional view illustrating a conventional stacked semiconductor package.

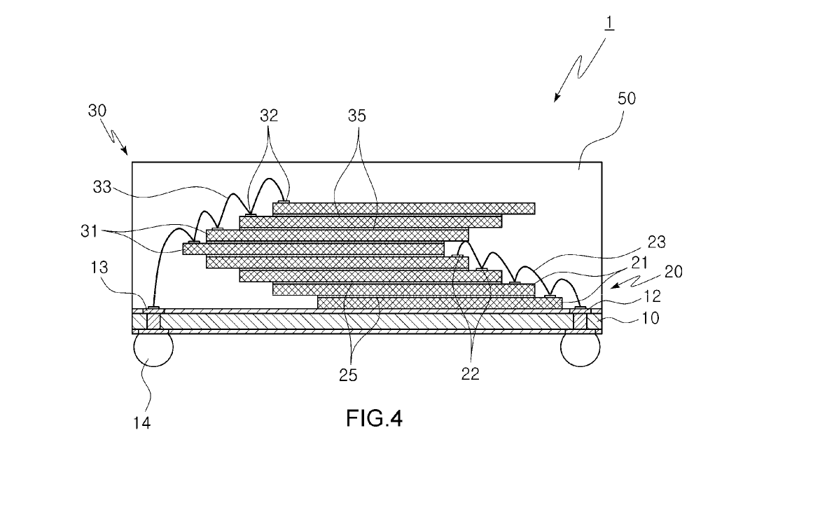

### MODE FOR INVENTION

Hereinafter, a detailed description will be given of the preferred embodiments of the present invention with reference to the appended drawings.

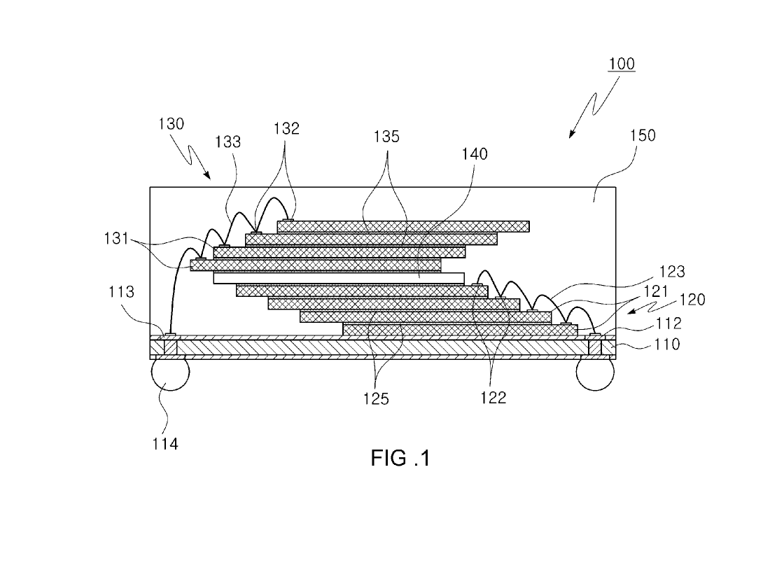

According to a first embodiment of the present invention, as illustrated in FIG. 1, a stacked semiconductor package 100 includes a substrate 110, a first cascade chip-layered body 120, a spacer 140, a second cascade chip-layered body 130, a first, second conductive wire 123, and a second conductive wire 133.

The substrate 110 includes a first connection pad 112 which is wire-bonded to the end of the first conductive wire 123 and a second connection pad 113 which is wire-bonded to the end of the second conductive wire 113 on the upper surface of the substrate on which the first cascade chip-layered body 120 and the second cascade 130 are continuously stacked.

Such a substrate 110 has solder balls 114 applied on ball lands on the lower surface thereof so as to be electrically connected to a main board (not shown), and thereby may be provided as a printed circuit board which may be mounted on the main board.

The first cascade chip-layered body 120 includes a plurality of first semiconductor chips 121 stacked in two or more layers on the upper surface of the substrate 110, and the plurality of semiconductor chips 121 includes first bonding pads 122, which are wire-bonded to the first conductive wire 123 on the upper surface of one end of each thereof, and these chips are stacked in a stepped shape tilted to the left side in the drawing so that the first bonding pads 122 are externally exposed.

The spacer 140 is provided at a predetermined thickness between the first cascade chip-layered body 120 and the second cascade chip-layered body 130, and such a spacer 140 is disposed on the upper surface of the uppermost semiconductor chip so as to externally expose the first bonding pad 122 of the uppermost semiconductor chip 121 of the first cascade chip-layered body 120.

Thus, the mounting position of the second cascade chip-layered body 130 is increased by the thickness of the spacer 140, and thereby a gap between the first bonding pad 122 of the uppermost semiconductor chip 121 of the first cascade chip-layered body 120 and the upper overhang region of the first cascade chip-layered body 130 corresponding thereto is enlarged to ensure a space.

Such a spacer 140 is made of a material such as silicone, or a thermally conductive material having high thermal conductivity so as to easily dissipate heat generated from the semiconductor chips to the outside.

The second cascade chip-layered body 130 includes a plurality of second semiconductor chips 131 stacked in two or more layers on the upper surface of the spacer 140, and the plurality of second semiconductor chips 131 is obliquely stacked in a stepped shape so that the second bonding pads 132 formed on the upper surface of one end of each thereof are externally exposed upward.

As such, the semiconductor chips 131 of the second cascade chip-layered body 130 are stacked in the converted direction so that the second bonding pads 132 of the second semiconductor chips 131 and the first bonding pads 122 of the first semiconductor chips 121 are disposed in opposite directions.

The first and second semiconductor chips 121, 131 may include any one selected from among memory chips such as SRAM and DRAM, digital integrated circuit chips, RF integrated circuit chips, and base band chips, depending on the type of setting device to which the package is applied.

Meanwhile, as illustrated in FIG. 1, the spacer 140 may be disposed in a stepped shape between the uppermost semiconductor chip 121 of the first cascade chip-layered body 120 and the lowermost semiconductor chip 131 of the second cascade chip-layered body 130 so that the lower surface of one end of the spacer is exposed downward.

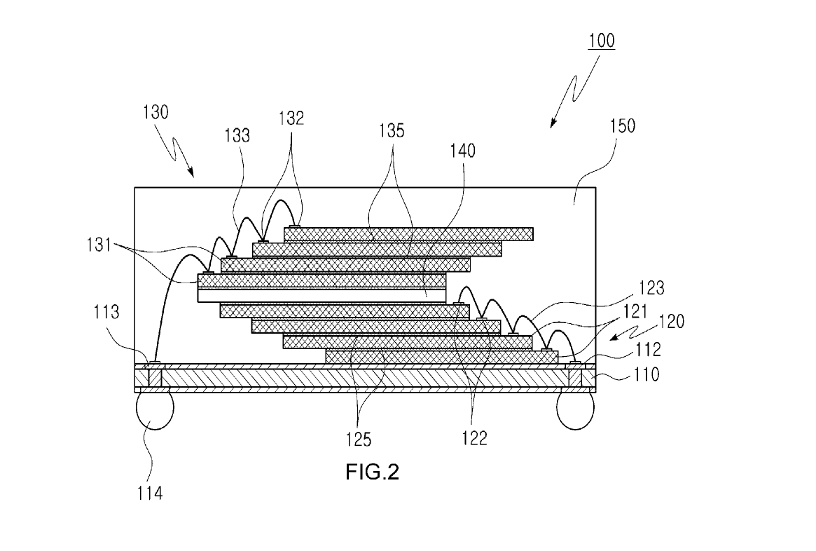

Also, as illustrated in FIG. 2, the spacer 140 may be disposed to overlap with the uppermost semiconductor chip 121 of the first cascade chip-layered body 120 so that the lower surface of one end of the spacer is exposed downward.

The first conductive wire 123 is composed of a wire member having a predetermined length connected between the first bonding pads 122 formed on the upper surface of one end of each of the first semiconductor chips 121 and the first connection pad 112 formed on the upper surface of the substrate 110 so that the plurality of first semiconductor chips 121 of the first cascade chip-layered body 120 is electrically connected to the substrate 110.

Upon wire bonding between the first bonding pads 122 of the semiconductor chips 121 and the first connection pad 112 of the substrate 110 by means of the first conductive wire 123 using a wire bonding machine, the spacer 140 provided between the first cascade chip-layered body 120 and the second cascade chip-layered body 130 enables a space having a large vertical gap to be ensured between the first bonding pad 122 of the uppermost semiconductor chip 121 of the first cascade chip-layered body 120 and the upper overhang region of the second cascade chip-layered body 130. Thereby, the loop at the top of the first conductive wire 123 one end of which is wire-bonded to the first bonding pad 122 of the uppermost semiconductor chip 121 may be prevented from coming into contact with the second semiconductor chip 131, thus warding off an electrical short.

Furthermore, contact between the second semiconductor chips 131 and the first conductive wire 123 which is swept due to a resin injected upon forming a molding unit 150 on the substrate may be prevented, thus warding off an electrical short.

The second conductive wire 133 is composed of a wire member having a predetermined length connected between the second bonding pads 132 which are externally exposed upward on the upper surface of one end of each of the second semiconductor chips 131 and the second connection pad 113 formed on the upper surface of the substrate 110 so that the plurality of second semiconductor chips 131 of the second cascade chip-layered body 130 is electrically connected to the substrate 110.

Also, a support member 145 having a predetermined height may be provided on the upper surface of the substrate 110 corresponding to the lower surface of one end of the spacer 140 so that the upper end of the support member is in contact with one end of the spacer 140 to support the second cascade chip-layered body 130.

As such, the support member 145 is illustratively explained to be provided on the upper surface of the substrate so that the upper end of the support member 145 is in contact with one end of the spacer 140 overlapping with the lowermost semiconductor chip 131 of the second cascade chip-layered body 130, but the present invention is not limited thereto, and it may be provided on the upper surface of the substrate 110 so that the upper end thereof is in contact with one end of the semiconductor chip 131 protruding from the spacer 140 to the outside.

Thus, upon wire bonding between the second bonding pads 132 of the semiconductor chips 131 and the second connection pad 113 of the substrate 110 by means of the second conductive wire 133 using a wire bonding machine, because the second cascade chip-layered body 130 may be supported and reinforced by the support member 145 the upper end of which is in contact with the spacer 140 or the semiconductor chip 131, it is possible to prevent movement of the second cascade chip-layered body 130 obliquely stacked on the upper surface of the spacer 140 due to an external force applied directly downward or cracking attributed to damage to the semiconductor chips 121 of the first cascade chip-layered body 120.

Furthermore, the support member 145 may be made of an elastic material such as a resin so as to elastically support loads of all of the semiconductor chips of the second cascade chip-layered body 130, or of a thermally conductive material such as copper, aluminum, etc. having high thermal conductivity so as to guide heat generated from the chips upon driving of the semiconductor chips to the substrate 110 so as to dissipate it.

Meanwhile, the substrate 110 includes a molding unit 150 made of a resin sealing material such as an epoxy molding compound to cover the first cascade chip-layered body 120, the second cascade chip-layered body 130, and the first and second conductive wires 123, 133 so as to protect them from an external environment such as corrosion or external physical damage, thereby forming a single package.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A stacked semiconductor package, comprising:
a substrate having a first connection pad and a second connection pad formed on an upper surface thereof;
a first cascade chip-layered body comprising a plurality of first semiconductor chips stacked in a stepped shape on the substrate so as to externally expose first bonding pads;
at least one spacer formed on an upper surface of an uppermost semiconductor chip of the first cascade chip-layered body so as to externally expose a bonding pad of the uppermost semiconductor chip;
a second cascade chip-layered body comprising a plurality of second semiconductor chips stacked in a stepped shape on an upper surface of the spacer so as to externally expose second bonding pads;
a first conductive wire which electrically connects the first bonding pads of the first semiconductor chips and the first connection pad of the substrate; and
a second conductive wire which electrically connects the second bonding pads of the second semiconductor chips and the second connection pad of the substrate.

2. The stacked semiconductor package of claim 1, wherein the spacer is disposed in a stepped shape between the uppermost semiconductor chip of the first cascade chip-layered body and a lowermost semiconductor chip of the second cascade chip-layered body.

3. The stacked semiconductor package of claim 1, wherein the spacer is disposed to overlap with the uppermost semiconductor chip of the first cascade chip-layered body so that a lower surface of one end thereof is exposed downward.

4. The stacked semiconductor package of claim 1, wherein a support member having a predetermined height is provided on the upper surface of the substrate so that an upper end of the support member is in contact with one end of the spacer or with one end of the semiconductor chip of the second cascade chip-layered body to support the second cascade chip-layered body.

5. The stacked semiconductor package of claim 1, wherein the substrate includes a molding unit which protects the first cascade chip-layered body and the second cascade chip-layered body from an external environment.
